(19) United States
(12) Patent Application Publication
(10) Pub. No.: US 2010/0233884 A1
(43) Pub. Date: Sep. 16, 2010

(54) PROCESSING APPARATUS AND METHOD FOR MAKING SEMICONDUCTOR DEVICES

(76) Inventor: JEN-SHENG LUNG, TAIPEI CITY (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/566,992

(22) Filed: Sep. 25, 2009

(30) Foreign Application Priority Data
Mar. 10, 2009 (TW) 097138043

(51) Int. Cl. H01L 21/306; B08B 3/10; C23F 1/08; B08B 13/00; B05C 9/10

(52) U.S. Cl. 438/745; 134/18; 156/345.11; 118/620; 257/E21.219

(57) ABSTRACT

A process apparatus and a method for making semiconductor devices is implemented in a semiconductor equipment and utilizes three magnetic objects arranged in a helical path. Chemicals within the chemical pipe are magnetized, and the chemicals include etch acids, photoresist stripper and clean chemicals. Then, efficiency of semiconductor process is increased.

### BACKGROUND OF THE INVENTION

(1) Field of the Invention

The invention relates to a processing apparatus and a method for making semiconductor devices, and more particularly a processing apparatus and a method implemented in a semiconductor process.

(2) Description of the Prior Art

Magnetism can be used to miniaturize molecule cluster. For example, limescale is not prone to deposit and water will be easily absorbed by human being after water is magnetized. As to aquaculture, magnetized water is prone to have higher amount of dissolved oxygen; and oil combustion rate is significantly increased after oil is magnetized so as to decrease air pollution and increase available amount of energy. Thus, it is advantageous for industries to use magnetism.

Magnetism is also utilized in dry process of semiconductor industry. For example, Taiwan Patent I239560, 00586335, 00419749, and 00403960 and U.S. Pat. No. 4,483,737 disclose dry processes for semiconductor manufacturing. However, wet processes for semiconductor manufacturing do not utilize magnetism to improve process.

As to wet process, it proceeds in a wet station so as to etch substrate by etch acids and to make treatment to the substrate by photoresist stripper. In addition, the substrate is rinsed by clean chemical such as de-ionized water.

To facilitate etching rate of wet process in semiconductor manufacturing usually uses heating in prior art so that viscosity of etch acid due to heating is getting smaller and etching rate is increased. Thus, friction between the etch acid and equipment which the etch acids is direct contact with is smaller due to smaller viscosity of etch acids. The equipment can be valves, pipelines, filters, motors, and containers, etc. To control the acid flow within the equipment must lower pressure loss. For example, etch acids such as phosphoric acid should be heated up to 150° C. However, in addition to equipment and the acid within the equipment resistant to high temperature, additional energy leads to higher cost and performance of etch is not easily controlled.

Therefore, the present invention provides a semiconductor process apparatus and a method for making semiconductor devices to overcome the above disadvantages.

### SUMMARY OF THE INVENTION

Accordingly, it is an object of the present invention to provide a processing apparatus and a method for making semiconductor devices so as to increase efficiency of semiconductor process in a stable way.

The present invention relates to a semiconductor processing apparatus and a method for making semiconductor devices. The present invention utilizes a semiconductor equipment and includes a pipeline and a plurality of magnetic objects.

The pipeline has a chemical pipe to convey aqueous-based chemicals such as etch acids, photoresist strippers, photoresist or clean chemicals. These aqueous-based chemicals are used in different stages of the process for semiconductor devices.

The magnetic objects are positioned in proximity with the perimeter of the pipeline, and parts of the magnetic objects with same magnetic pole are oriented toward the pipeline so as to magnetize the aqueous-based chemical within the chemical pipe of the pipeline. In addition, the magnetic objects are interlaced along a helical path. Thus, the magnetic objects are longitudinally and traversely interlaced along the pipeline so that uniform magnetic field lines are created.

Then, magnetized aqueous-based chemical within the chemical pipe of the pipeline is conveyed to a process workpiece such as a substrate so that the substrate can be subjected to the semiconductor process.

Therefore, the wet processing apparatus and the method for making semiconductor devices of the present invention magnetizes the aqueous-based chemicals including etch acids, photoresist strippers, photoresist or clean chemical so as to increase efficiency of semiconductor process in a stable and energy-saving way.

### BRIEF DESCRIPTION OF THE DRAWINGS

The present invention will now be specified with reference to its preferred embodiment illustrated in the drawings, in which:

FIG. 1 is a perspective view of a process apparatus according to a first embodiment of the present invention;

FIG. 2 is a perspective view of magnetic objects according to the present invention;

FIG. 3 is a flowchart of a method for making semiconductor devices according to the present invention; and

FIG. 4 is a schematic diagram of a process apparatus according to a second embodiment of the present invention.

### DESCRIPTION OF THE PREFERRED EMBODIMENT

In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

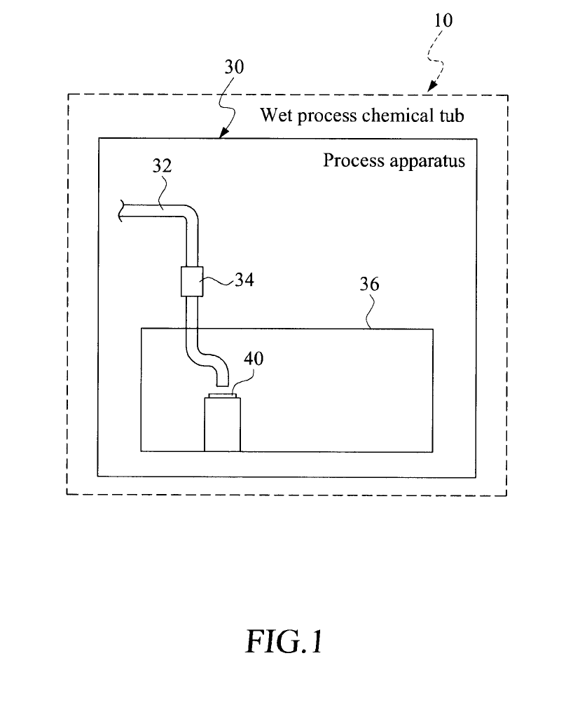

Referring to FIG. 1, it illustrates a schematic diagram of a semiconductor process apparatus 30 according to a first embodiment of the present invention. The semiconductor process apparatus 30 is implemented within a semiconductor equipment of semiconductor process. The semiconductor equipment can be a wet station 10 and includes a pipeline 32, a plurality of magnetic objects 34, and a process tub 36.

The pipeline 32 has a chemical pipe to convey aqueous-based chemicals such as etch acids, photoresist strippers or clean chemical. These aqueous-based chemicals are used in different stages of the wet semiconductor process for semiconductor devices.

The etch acids can be sulfuric acid (H₂SO₄) or phosphoric acid (H₃PO₄), and the photoresist strippers are used to strip intermediate material on the substrate due to the wet process. Clean chemical such as de-ionized water is used to rinse residual material on the substrate.

The etch process will be described in more detail as follows. The etch acids used in the etch process are always circulated. When we want to replace aqueous-based chemicals such as etch acids, a chemical distribution system is needed to distribute the aqueous-based chemicals. In addition, flow direction of the chemicals is unidirectional, that is, “flow in” and “drain out”. According to the present invention, the plurality of magnetic objects 34 are used to magnetize the etch acids within the pipeline 32.

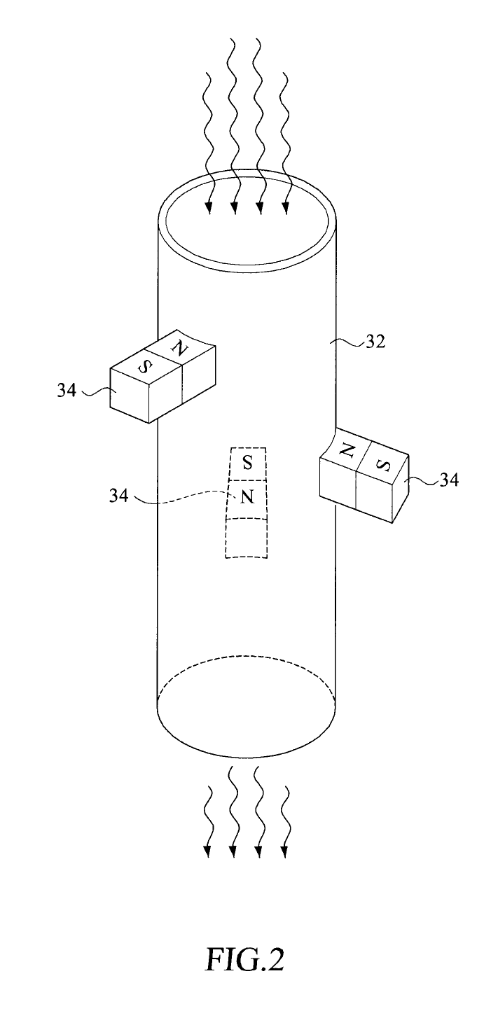

Referring to FIGS. 1 and 2, FIG. 2 illustrates a perspective view of the magnetic objects 34 according to the present invention. According to one embodiment of the present invention, three magnetic objects 34 are implemented in proximity with the perimeter of the pipeline 32. Parts of the magnetic objects 34 with same magnetic pole are oriented toward the pipeline 32 so as to magnetize the aqueous-based chemicals within the chemical pipe of the pipeline 32. Besides, the magnetic objects 34 are interlaced along a helical path. Thus, the magnetic objects 34 are longitudinally and traversely interlaced along the pipeline 32 so that uniform magnetic field lines are created.

Further referring to FIG. 1, magnetized aqueous-based chemical within the chemical pipe of the pipeline 32 is conveyed to the process tub 36. When the aqueous-based chemical is the etch acid, the process tub 36 is an etch tub. When the aqueous-based chemical is the photoresist strippers, the process tub 36 is a stripping tub. Similarly, when the aqueous-based chemical is clean chemical, the process tub 36 is a rinse tub.

Then, magnetized aqueous-based chemical within the chemical pipe of the pipeline 32 is conveyed to the process tub 36 so as to process a process workpiece 40 such as a substrate (the substrate can be a wafer) so that the substrate can be subjected to the wet semiconductor process. According to the present invention, the substrate can be silicon substrate, III-V compound substrate in integrated circuits industry or resin substrate in printed circuit board industry.

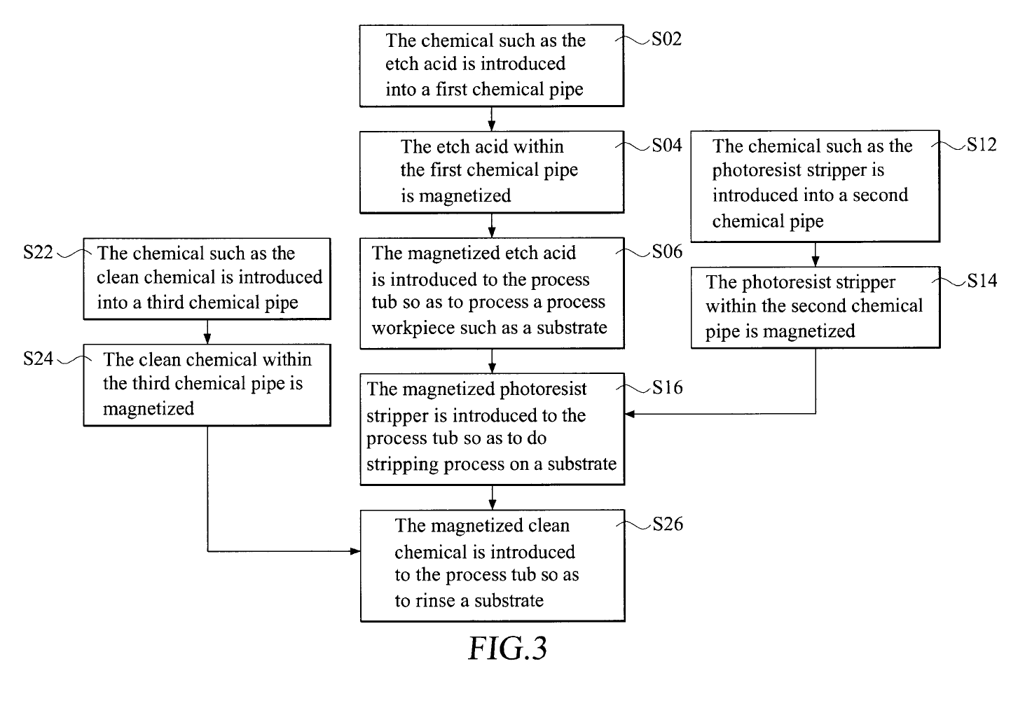

Referring to FIG. 3, it shows a flowchart of a method for making semiconductor devices according to the present invention. The present invention also relates to a method for making semiconductor devices and implemented in a wet process tub 10. The method of the present invention includes the following steps.

Step S02: The chemical such as the etch acid is introduced into a first chemical pipe. Then, the method proceeds to the step S04.

Step S04: The etch acid within the first chemical pipe is magnetized. Then, the method proceeds to the step S06.

Step S06: The magnetized etch acid is introduced to the process tub so as to process a process workpiece 40 such as a substrate and to start the wet etch process. Then, the method proceeds to the step S16.

Step S12: The chemical such as the photoresist stripper is introduced into a second chemical pipe. Then, the method proceeds to the step S14.

Step S14: The photoresist stripper within the second chemical pipe is magnetized. Then, the method proceeds to the step S16.

Step S16: The magnetized photoresist stripper is introduced to the process tub so as to do stripping process on a process workpiece 40 such as a substrate and to start the wet etch process. Then, the method proceeds to the step S26.

Step S22: The chemical such as the clean chemical is introduced into a third chemical pipe. Then, the method proceeds to the step S24.

Step S24: The clean chemical within the third chemical pipe is magnetized. Then, the method proceeds to the step S26.

Step S26: The magnetized clean chemical is introduced to the process tub so as to rinse a process workpiece 40 such as a substrate and to start the wet etch process.

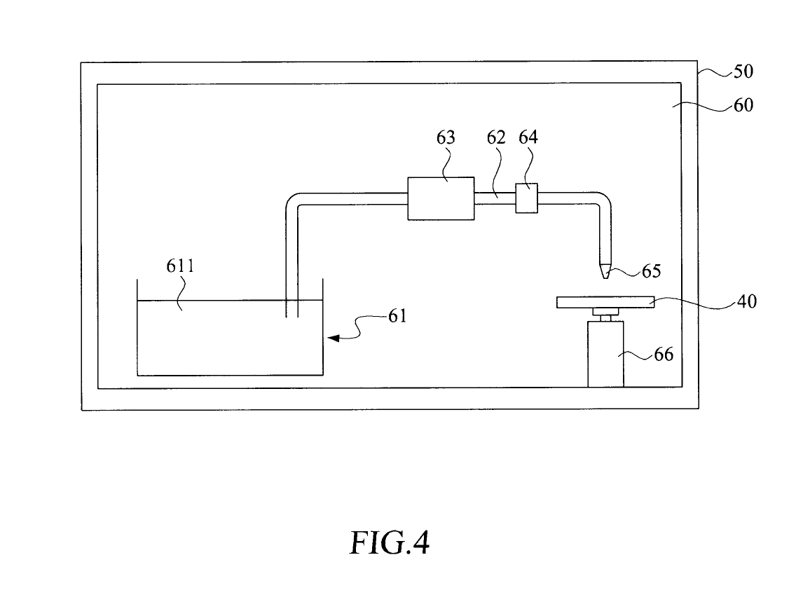

Referring to FIG. 4, it illustrates a schematic diagram of a semiconductor process apparatus according to a second embodiment of the present invention. The semiconductor equipment 60 is implemented within a semiconductor equipment of lithography process. The semiconductor equipment 60 can be a coater 50. The semiconductor equipment 60 includes a photo resistor container 61, a pipeline 62, a pumping device 63, a plurality of magnetic objects 64, a nozzle 65, and a spin table 66. The photo resistor container 61 is filled with chemical liquid 611. The magnetic objects 64 are implemented in proximity with the perimeter of the pipeline 62, as the first embodiment. In this embodiment, the process workpiece 40 can be a wafer putted on the spin table 66.

In this embodiment, the chemical liquid 611 can be photoresist. The chemical liquid 611 within the photo resistor container 61 can be drawn via the pipeline 62 by the pumping device 63. When the chemical liquid 611 is conveyed via pipeline 62 and is magnetized by the magnetic objects 64 surrounding with the pipeline 62 (please refer to the first embodiment), the chemical liquid 611 flows out of the nozzle 65 to center of the process workpiece 40. Moreover, via the process workpiece 40 rotate with the spin table 66, the chemical liquid 611 is coated of the surface of the process workpiece 40 completely and uniformly.

The process workpiece 40 is coated with 1 to 2.5 ml of photoresist, because the high viscosity of the photoresist in the prior art. However, the volume, such as 0.8 to 0.9 ml, of photoresist coated on the process workpiece is decreased, because the chemical liquid 611 is magnetized by the magnetic objects 64 surrounding the pipeline 62 of the present invention.

Therefore, the present invention includes a wet processing apparatus and a method for making semiconductor devices. The chemicals such as etch acids, photoresist strippers, photoresist or clean chemicals are magnetized so as to increase efficiency of semiconductor process in a stable and energy-saving way.

While the present invention has been particularly shown and described with reference to a preferred embodiment, it will be understood by those skilled in the art that various changes in form and detail may be without departing from the spirit and scope of the present invention.

I claim:

1. A method for making semiconductor devices in a semiconductor equipment, comprising the steps:
introducing a chemical into a pipeline;
magnetizing the chemical within the pipeline; and
conveying the magnetized chemical to a process workpiece.

2. The method according to claim 1, wherein the pipeline includes a chemical pipe and three magnetic objects, and the three magnetic objects are interlaced along a helical path and are longitudinally and traversely interlaced along the chemical pipe and are positioned in proximity with the perimeter of the chemical pipe, and parts of the magnetic objects with same magnetic pole are oriented toward the chemical pipe.

3. The method according to claim 1, wherein the chemical is selected from a group of chemicals including etch acids, photoresist stripper, photoresist, and clean chemicals.

4. The method according to claim 1, wherein the process workpiece is a semiconductor substrate.

5. The method according to claim 1, wherein the semiconductor equipment is selected from a group of a wet process chemical tub and a coater.

6. A process apparatus for making semiconductor devices in a semiconductor equipment, comprising:
a pipeline having a chemical pipe to convey a chemical; and
a plurality of magnetic objects, positioned in proximity with the perimeter of the chemical pipe, and parts of the magnetic objects with same magnetic pole oriented toward the chemical pipe so as to magnetize the chemical within the chemical pipe of the pipeline;
wherein magnetized chemical within the chemical pipe of the pipeline is conveyed to a process workpiece so that the process workpiece is subjected to the semiconductor process.

7. The process apparatus according to claim 6, wherein the three magnetic objects are interlaced along a helical path so that the three magnetic objects are longitudinally and traversely interlaced along the pipeline.

8. The process apparatus according to claim 6, wherein the chemical is selected from a group of chemicals including etch acids, photoresist stripper, photoresist, and clean chemicals.

9. The process apparatus according to claim 6, wherein the process workpiece is a semiconductor substrate.

10. The process apparatus according to claim 6, wherein the semiconductor equipment is a wet process chemical tub, and the semiconductor process is a wet semiconductor process.

11. The process apparatus according to claim 6, wherein the semiconductor equipment is a coater and the semiconductor process is a semiconductor lithography process.
